(19) United States
(12) Patent Application Publication
(10) Pub. No.: US 2025/0035705 A1
(43) Pub. Date: Jan. 30, 2025

(54) ESTIMATING INFORMATION IN RELATION TO A CELLULAR BATTERY

(71) Applicant: STELLANTIS AUTO SAS, POISSY (FR)

(72) Inventor: Akram EDDAHECH, GUYANCOURT (FR)

(21) Appl. No.: 18/715,006

(22) PCT Filed: Oct. 17, 2022
(86) PCT No.: PCT/FR2022/051952

§ 371 Date: May 30, 2024

(30) Foreign Application Priority Data
Dec. 3, 2021 (FR) 2112900

(51) Int. Cl. G01R 31/367; B60L 58/14; B60L 58/16; G01R 31/382; G01R 31/388; G01R 31/389; G01R 31/392; G01R 31/396

(52) U.S. Cl. CPC G01R 31/367; B60L 58/14; B60L 58/16; G01R 31/382; G01R 31/388; G01R 31/389; G01R 31/392; G01R 31/396

(57) ABSTRACT

A method is provided for estimating at least one item of information in relation to a cellular battery of a system comprising N cells able to store electrical energy, where N>1, and each having a current state of charge, a current resistance state of health and a current capacity state of health. This method comprises a step (10-40) of estimating first information representative of a total energy available in the cellular battery as a function of the current resistance states of health, current capacity states of health and current states of charge, and of a time interval for which the cellular battery is allowed to discharge with a chosen discharge current and at a reference temperature.

### CROSS-REFERENCE TO RELATED APPLICATIONS

This application is the US National Stage under 35 USC § 371 of International Application No. PCT/FR2022/051952, filed Oct. 17, 2022, which claims the priority of French application No. 2112900 filed on Dec. 3, 2021, the content (text, drawings and claims) of both said applications being incorporated by reference herein.

### BACKGROUND

The described methods and devices concern cellular batteries, and more specifically the estimating of information(s) in relation to such batteries.

Some batteries, for example for vehicles, possibly of the automotive type, comprise at least two electrical energy storage cells, possibly electrochemical (for example, of the lithium-ion (or Li-ion) or Ni—Mh or Ni—Cd type). It should be noted that in the case of a vehicle, the cellular battery can be a so-called “main” (or traction) battery, as it is responsible for supplying electrical current to the vehicle's on-board network, via a converter, and to an electric prime mover of the vehicle's powertrain. But in the case of a vehicle, the cellular battery can also be a “service” battery, when it is of the very low voltage type (typically between 12 V and 48 V) and is responsible for supplying electrical current to the vehicle's on-board network in the absence of a main battery (and therefore of an electric prime mover), or in place of or in addition to a main vehicle battery.

In the following and the preceding, the term “on-board network” refers to a power supply network to which electrical (or electronic) equipment (or components) consuming electrical energy are connected. As is well known to the person skilled in the art, some of the parameters of today's cellular batteries are managed so that they can be used optimally, with a minimized risk of failure and incident, for example for the safety and peace of mind of vehicle users. One of the aims of this management system is to enable cellular battery diagnostics, which in turn optimize use, reduce repair costs and anticipate major malfunctions.

The parameters managed include the energy available in the cellular battery and the cellular battery's state of health of energy (SOHE), which are used, for example, to estimate a vehicle's range as accurately as possible, so as not to overestimate or underestimate performance. Recall that the estimated available energy is used to estimate the state of health of energy (or SOHE).

At present, at least four solutions have been proposed for estimating available energy.

A first solution consists in estimating the energy available in the cellular battery, taking into account which cell is the most limiting at the moment in question, and using maps previously built up from characterizations of new cells, giving the energy available as a function of the state of charge (or SOC) and internal temperature of each cell in the cellular battery.

This first solution provides estimates of available energy that are too pessimistic, as it takes into account the cell with the lowest electrical energy storage capacity in the cellular battery (and therefore the smallest SOHC (State of Health of Capacity) of all the cells), or with the lowest state of charge in the cellular battery, or with the lowest internal temperature in the cellular battery. What's more, the estimates are approximate, since they are based on maps obtained during cell characterizations that are not necessarily representative of those used in the cellular battery under consideration, and less accurate in the case of dispersed cell production.

A second solution is to estimate the energy available in the cellular battery, taking into account only the current estimated capacities of each cell in the cellular battery, and therefore their respective SOHCs. This second solution provides estimates of available energy that are not very accurate, and the closer the cells are to their end-of-life, the less accurate they become. This is because the resistance states of health (or SOHR (“State of Health of Resistance”) of each cell are not taken into account, even though they increase with age, and therefore have a greater impact on energy dissipation.

A third solution is to estimate the energy available in the cellular battery using a durability model that has been calibrated off-line, for example elsewhere than at the facility of a vehicle manufacturer (which is usually tasked with assembling the cells as needed). Each durability model calibrated off-line requires an extensive characterization scheme for accelerated cell aging under different conditions, but which is not capable of accounting for a sudden loss of energy from a cell at end-of-life due to usage outside the limits of the experimental design initially tested.

A fourth solution is to estimate the energy available in the cellular battery using a “black box” (or artificial intelligence) learning method that uses an off-line database, for example one remote from a vehicle. These learning methods require very rich databases, don't offer true real-time responsiveness, monopolize a lot of wireless network bandwidth, and give inaccurate estimates when the cellular battery is used outside the learning limits.

The described methods and devices therefore aim especially to improve the situation.

### SUMMARY

To this end, the company proposes a method for estimating information intended for implementation in a system comprising a cellular battery comprising N cells able to store electrical energy, where N>1, and each having a current state of charge, a current resistance state of health and a current capacity state of health.

This method of estimating information is characterized by the fact that it comprises a step in which first information representative of a total energy available in the cellular battery is estimated as a function of current resistance states of health, current capacity states of health and current states of charge, and of a time interval for which the cellular battery is allowed to discharge with a chosen discharge current and at a reference temperature.

By taking into account the parameters that define the actual state of each cell in the cellular battery, the system provides a particularly accurate and reliable estimate of the first information (representing the total energy available in the cellular battery).

The method for estimating information may include other features which can be taken separately or in combination, and especially:
in its step the first information can be further estimated as a function of initial electrical energy storage capacities of each of the cells and initial maximum states of charge of each of the cells;
in its step, the first information can be further estimated as a function of selected theoretical models representative of equivalent resistances of each of the cells;
in its step, the first information can be estimated additionally as a function of open-circuit voltage sums of each of the cells for state-of-charge values between a maximum state-of-charge and a state-of-charge at the end of the time interval;
in its step, the time interval can be selected as a function of a minimum cutoff voltage of a cell below which discharge of the cellular battery with the chosen discharge current is prevented and/or a minimum state of charge of a cell below which discharge of the cellular battery with the chosen discharge current is prevented;
in the presence of the last option, in its step a first theoretical time interval can be determined as a function of the minimum cutoff voltage, current electrical energy storage capacities of each of the cells, the selected discharge current, selected theoretical models representative respectively of equivalent resistances of each of the cells, and initial states of charge of each of the cells, and a second theoretical time interval as a function of the minimum state of charge, the selected discharge current, the current electrical energy storage capacities and the initial states of charge, then the time interval can be selected by taking the shorter of these first and second theoretical time intervals;
in its step, second information representative of a state of health of energy of the cellular battery can be estimated as a function of the first information and a useful energy at the beginning of the cellular battery's life.

Also proposed is a computer program product comprising a set of instructions which, when executed by processing means, is suitable for implementing an information estimating method of the type presented above for estimating at least one item of information in relation to a cellular battery of a system comprising N cells able to store electrical energy, where N>1.

Also proposed is a device for estimating information intended to equip a system comprising a cellular battery comprising N cells able to store electrical energy, where N>1, and each having a current state of charge, a current resistance state of health and a current capacity state of health.

This device for estimating information is characterized by the fact that it comprises at least one processor and at least one memory to carry out operations consisting of estimating first information representative of a total energy available in the cellular battery is estimated as a function of current resistance states of health, current capacity states of health and current states of charge, and of a time interval for which the cellular battery is allowed to discharge with a chosen discharge current and at a reference temperature.

Also proposed is a system, possibly a vehicle, and comprising, on the one hand, a cellular battery comprising N cells able to store electrical energy, where N>1, and each having a current state of charge, a current resistance state of health and a current capacity state of health, and, on the other hand, a device for estimating information of the type presented above.

### BRIEF DESCRIPTION OF THE FIGURES

Other features and advantages will become apparent from examining the detailed description hereinafter, and the appended drawings, in which:

FIG. 1 schematically and functionally shows an example of a vehicle comprising a powertrain with an electric prime mover powered by a cellular battery, and a device for estimating information(s).

FIG. 2 schematically and functionally shows an example of a battery computer comprising a device for estimating information(s).

FIG. 3 schematically shows an example of an algorithm implementing a method for estimating information.

### DETAILED DESCRIPTION

In particular, the purpose is to propose a method for estimating information(s), and an associated device for estimating information(s) DEI, designed to enable accurate and reliable estimation of at least one item of information in relation to a cellular battery BC of a system V comprising N cells CE.

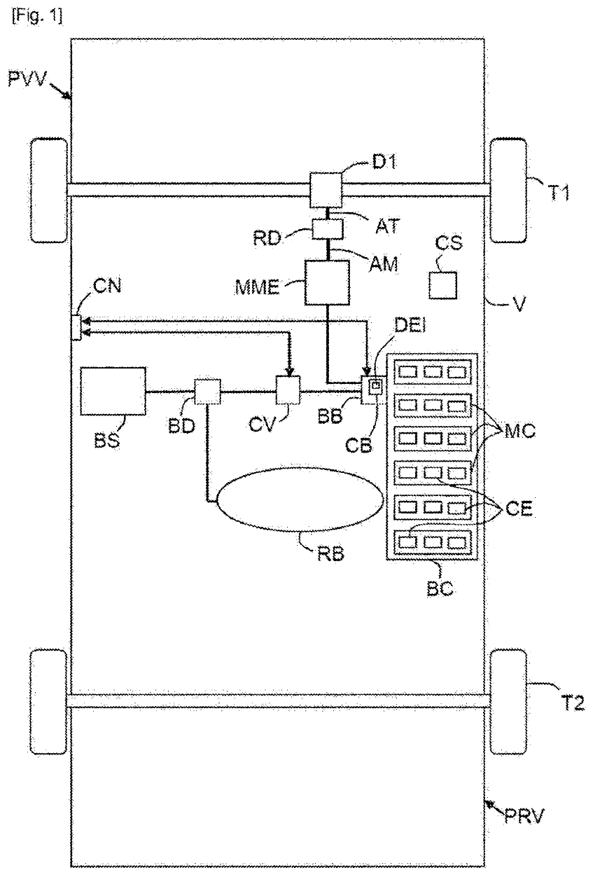

In the following, by way of a non-limiting example, the system V is assumed to be a motor vehicle, such as a car, as shown in FIG. 1. However, described methods and device are not limited to this type of system. It relates to any type of system comprising at least one rechargeable cellular battery (in any mode). Thus, it relates, for example, to land vehicles (commercial vehicles, campers, minibuses, coaches, trucks, motorcycles, road machines, construction machines, agricultural machines, recreational machines (snowmobiles, go-carts) and tracked machines), boats and aircraft, but also any fixed or stationary system, such as an electrical power supply installation and, more generally, any electronic device (including high-consumption ones), any building or any installation (including industrial ones). By way of illustration, the cellular battery BC of the system V can be connected to a renewable energy source (notably photovoltaic or wind power).

By way of a non-limiting example, we consider that the system V (in this case a vehicle) comprises an all-electric powertrain (i.e. the drive is provided exclusively by at least one electric prime mover MME). However, the powertrain could be hybrid (combustion and electric) or purely combustion.

In the following, by way of a non-limiting example, the cellular battery BC is assumed to be a main (or traction) battery. However, the cellular battery that is the subject of the estimated information(s) could be a service battery (possibly rechargeable via a converter supplied with electrical energy by a main battery).

FIG. 1 shows schematically a system V (here a vehicle) comprising an electric power train, an on-board network RB, a power supply unit comprising a service battery BS and (here) an electric energy generator GE associated with a cellular battery BC, and an information estimation device DEI.

The on-board network RB is a power supply network to which electrical (or electronic) equipment (or components) that consume electrical energy are connected.

The service battery BS is responsible for supplying electrical energy to the on-board network RB, in addition to that supplied by the electrical energy generator GE fed by the cellular battery BC, and sometimes in place of this electrical energy generator GE (particularly when the powertrain is asleep and the electrical energy generator GE inactive). For example, the service battery BS may be a very low-voltage battery (typically 12 V, 24 V or 48 V). It can be recharged at least by the electric generator GE. As a non-limiting example, the service battery BS is of the 12 V lithium-ion type.

The drive chain has a powertrain which is, in this case, purely electrical, and therefore comprises, in particular, an electric prime mover MME, a drive shaft AM, and a transmission shaft AT. The term “electric prime mover” is used here to mean an electrical machine designed to supply or recover torque to move the system V (in this case, a vehicle). The operation of the powertrain is supervised by a supervision computer CS.

The electric prime mover MME (here an electric motor) is coupled to the cellular battery BC, in order to be supplied with electrical energy, as well as possibly to supply this cellular battery BC with electrical energy during a regenerative braking phase. It is coupled to the drive shaft AM, to provide it torque by rotation. This drive shaft AM is coupled to a reduction gearbox RD which is also coupled to the drive shaft AT, itself coupled to a first set T1 (in this case a wheel set), preferably via a differential D1.

This first set T1 is located in the front part PW of the vehicle V. But in one variant, this first set T1 could be the one referred to here as T2, located in the rear part PRV of the vehicle V.

Here, the prime mover MME is also coupled to the electrical energy generator GE, which is also indirectly coupled to the service battery BS, in particular to recharge it with converted electrical energy from the cellular battery BC.

This electrical energy generator GE is a current converter electrically coupled to the charging connector CN of the vehicle V, by way of example. It is also responsible for supplying the on-board network RB with electrical energy from the cellular battery BC, which is converted when the powertrain is operating, or when the powertrain is asleep but the vehicle V is recharging its cellular battery BC, in addition to recharging the service battery BS.

In the non-limiting example shown in FIG. 1, the cellular battery BC is suitable not only for recharging in mode 2 or 3, but also for recharging in mode 4.

For example, the cellular battery BC may comprise electrochemical electrical energy storage cells CE, possibly of the lithium-ion (or Li-ion) or Ni—Mh or Ni—Cd type. Also, for example, the cellular battery BC can be of the low-voltage type (typically 450 V by way of illustration). But it could be medium-voltage or high-voltage.

As shown in FIG. 1, the cells CE can be part of modules MC which are coupled together, for example in series, within the cellular battery BC. The term “module MC” refers to a group of at least one cell CE. When a module MC comprises several cells CE, these cells (CE) can be coupled together in series and/or in parallel.

Note that the cellular battery BC is associated with a battery box BB, which particularly comprises means for measuring voltage, current and internal temperature (not shown) and a battery computer CB. This battery computer centralizes current measurements, voltage measurements and internal temperature measurements (including those relating individually to each of the N cells CE), and estimates parameters of the cellular battery BC on the basis of these measurements, including its internal resistance, minimum voltage and current state of charge (or SOC).

It should also be noted that in the non-limiting example shown in FIG. 1, the vehicle V further comprises a distribution box BD to which the service battery BS, the electrical energy generator GE and the on-board network RB are coupled. This distribution box BD is responsible for distributing to the on-board network RB the electrical energy produced by the electrical energy generator GE or stored in the service battery BS, in order to supply the electrical components (or equipment) coupled to the on-board network RB, according to the supply requests received (notably from the powertrain's supervision computer CS).

As mentioned above, proposed here is a method for estimating information(s) intended to enable accurate and reliable estimation of at least one item of information ibn in relation to a cellular battery BC of a vehicle V comprising N cells CE (i), where N>1. In the following, “i” is an index that designates each cell CE, and therefore takes values between 1 and N.

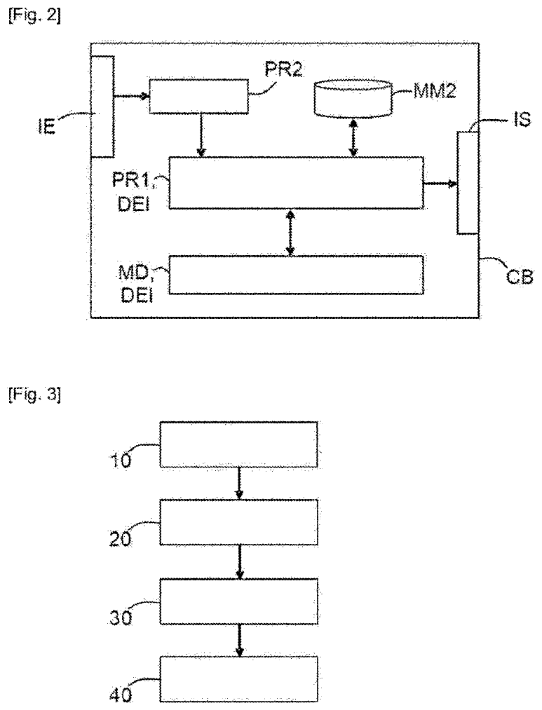

This (information estimation) method can be implemented at least in part by the information estimation device DEI (shown in FIGS. 1 and 2), which for this purpose comprises at least one processor PR1, for example a digital signal processor (or DSP), and at least one memory MD. This information estimation device DEI can therefore be implemented in the form of a combination of electrical or electronic circuits or components (or “hardware”) and software modules (or “software”).

The memory MD is RAM in order to store instructions for implementing by the processor PR1 at least part of the control method for estimating information. The processor PR1 may comprise integrated circuits (or printed circuits), or several integrated circuits (or printed circuits) connected by wired or wireless connections. Integrated circuit (or printed circuit) means any type of device capable of performing at least one electrical or electronic operation.

In the non-limiting example shown in FIGS. 1 and 2, the information estimation device DEI is part of the battery computer CB (and therefore the battery box BB). But this is not mandatory. Indeed, the information estimation device DEI could comprise its own dedicated computer, which can then be coupled to the battery computer CB.

As shown non-limitingly in FIG. 3, the method (of estimating information) comprises a step 10-40 which is implemented in the vehicle V each time an estimate of at least a first item of information ib1 (n=1), representative of the total energy E_{tot ref} available in the cellular battery BC, is requested, for example by the battery computer CB.

This step 10-40 comprises a sub-step 30 in which the first information ib1 is estimated as a function of the current resistance states of health SOHRᵢ of each of the N cells CE, the current capacity states of health SOHCᵢ of each of the N cells CE, the current states of charge SOCᵢ of each of the N cells CE, and a time interval Δt_{end} during which the cellular battery BC is allowed to discharge under a selected discharge current I_{dc} and at a reference temperature Tref.

Thanks to this consideration of at least the parameters SOHRᵢ, SOHCᵢ and SOHᵢ, which define the actual state of each of the cells CE in the cellular battery BC (and not just the most limiting one), a particularly accurate and reliable estimate of the first information ib1 (representative of the total energy E_{tot ref} available in the cellular battery BC) is now available in the vehicle V, in real time.

It will be understood that it is at least the processor PR1 and memory MD of the estimation device DEI that are arranged to perform the operations consisting in estimating the first information ib1 as a function of the resistance states of health SOHRᵢ, the capacity states of health SOHC, the states of charge SOCᵢ, and the time interval Δt_{end} during which a discharge of the cellular battery BC is allowed under the chosen discharge current I_{dc} and at the reference temperature Tref.

For example, the reference temperature Tref may be 25° C. But other values can also be used.

Also, for example, the discharge current I_{dc} can be chosen so as to obtain a discharge rate equal to a third of the total capacity (i.e. C/3), particularly when the powertrain is all-electric. But other discharge current values lac can also be used.

Note that step 10-40 may also include a preliminary sub-step 10 in which all resistance states of health SOHRᵢ, capacity states of health SOHCᵢ and states of charge SOCᵢ are estimated from the voltage, current and internal temperature measurements of each cell CE (i). It is recalled that each capacity state of health SOHC is estimated from the state of charge SOC, that each resistance state of health SOHRᵢ is estimated from the state of charge SOCᵢ and the associated internal temperature, and that each state of charge SOCᵢ is itself estimated from previous estimates of the resistance state of health SOHR and the SOHCᵢ capacity state of health within a feedback loop.

The resistance states of health SOHR and/or capacity states of health SOHCᵢ and/or states of charge SOC can be estimated by the information estimation device(s) DEI or by the battery computer CB.

It should also be noted that step 10-40 may also comprise a preliminary sub-step 20 in which the time interval Δt_{end} is selected as a function of a minimum cutoff voltage U_{cutoff_min} of a cell CE below which discharge of the cellular battery BC with the chosen discharge current I_{dc} is prohibited and/or a minimum state of charge SOC_{min_threshold} of a cell CE below which discharge of the cellular battery BC with the chosen discharge current I_{dc} is prohibited.

In the presence of the latter option, a first theoretical time interval Δt_{end}^{U} and a second theoretical time interval Δt_{end}^{SOC} can be determined in sub-step 20 of step 10-40, for example.

The first theoretical time interval Δt_{end}^{U} is determined as a function of the minimum cutoff voltage U_{cutoff_min}, the current electrical energy storage capacities capai of each of the cells CE, the chosen discharge current I_{dc}, the chosen theoretical models (representative respectively of the equivalent resistances Rᵢ of each of the cells CE), and the initial states of charge SOC_{ini.i} of each of the cells CE.

For example, the equivalent resistance Rᵢ can be simplified by the following equation:

$${R}_{i} = {R}_{0 , i} + {R}_{1 , i} ( 1 - exp ( \frac{- Δ {t}_{end}}{Tau} ) )$$

where R_{0,i} is the open-circuit resistance of the circuit representing the cell CE (i), R_{1,i} is the internal resistance of the cell CE (i), and Δt_{end} (=t_{end}−tᵢₙᵢ) is the discharge time between the initial time tᵢₙᵢ and the final time t_{end}.

Note that the above equation can be replaced to a first approximation by the equation:

Rᵢ=R_{0,i}+R_{1,i}

Also for example, using for each of the cells CE the approximate equivalent resistance indicated above (Rᵢ=R_{0,i}+R_{1,i}), the first theoretical time interval Δt_{end}^{U} can be determined by means of the following equation:

$$Δ {t}_{end}^{U} = min ( \frac{3600 * {capa}_{i}}{{I}_{dc}} [ {SOC}_{ini , i} - {OCV}^{- 1} ( ( {U}_{cutoff \_ min} + {I}_{dc} * [ {R}_{0 , i} + {R}_{1 , i} ] ) ] ) .$$

The second theoretical time interval Δt_{end}^{SOC} is determined as a function of the Lend minimum state of charge SOC_{min_threshold}, the selected discharge current I_{dc}, the current electrical energy storage capacities capaᵢ, and the initial states of charge SOC_{ini,j}. It will be understood that reaching SOC_{min_threshold} at the end of discharge is a constraint linked to the durability of the cellular battery BC, or to the risk of not achieving minimum power performance.

For example, by targeting Δt_{end}^{SOC} when a cell state of charge SOCᵢ reaches the minimum state of charge SOC_{min_threshold}, the second theoretical time interval Δt_{end}^{SOC} be determined by means of the following equation:

$$Δ {t}_{end}^{SOC} = min ( \frac{3600 * {Capa}_{j}}{{I}_{dc}} ( {SOC}_{min \_ threshold} ) ) .$$

Then, in sub-step 20 of step 10-40, the time interval Δt_{end} can be selected by taking the smaller of the first and second theoretical time intervals (i.e Δt_{end}=min (Δt_{end}^{SOC}, Δt_{end}^{U})).

It should also be noted that in sub-step 30 of step 10-40 the first information ib1 can also be estimated as a function of the initial electrical energy storage capacities capai (at tᵢₙᵢ) of each of the cells CE and the initial maximum states of charge SOC_{max,i} of each of the cells CE.

It should also be noted that in sub-step 30 of step 10-40, the first information ib1 can also be estimated as a function of selected theoretical models representing the equivalent resistances Ri.

For example, we can use the same theoretical “RC” model for each cell CE, which represents it within an RC circuit, and in which the voltage Uᵢ across a cell CE (i) is given by the following equation: Uᵢ=OCV(SOCᵢ)+R_{1,i}*I_{dc},
where OCV (SOC) is the open circuit voltage of the cell CE (i) in the presence of a state of charge SOCᵢ.

Note that open-circuit voltage can be given by the following equation

$$OCV ( {SOC}_{i} ) = OCV ( {SOC}_{i} ) = OCV ( {SOC}_{ini , i} - \frac{{t}_{end} - {t}_{ini}}{3600 * {Capa}_{i}} {I}_{dc} )$$

here SOC_{ini.i} is the initial state of charge of the cell CE (i) at the initial time tᵢₙᵢ at the beginning of discharge.

More complex theoretical models than the RC model can be used, such as a theoretical model in which a combination of at least two RC circuits connected in parallel is used for each cell CE (i), instead of a single RC circuit.

It should also be noted that in sub-step 30 of step 10-40 the first information ib1 can also be estimated as a function of sums of the open-circuit voltage OCVᵢ of each of the cells CE for state-of-charge values between a maximum state-of-charge SOC_{max,i} and a state-of-charge SOC_{end,i} at the end of the time interval Δt_{end}.

For example, the sums of the open-circuit voltage OCVᵢ of each cell CE (i) can be determined by means of the following integral:

∫_{SOCini,i}^{SOCend,i}OCVᵢ(SOC)dSOC.

Also, for example, each final state of charge SOC_{end,i} can be determined using the following equation:

$${SOC}_{end , i} = S O {C}_{ini , i} - \frac{Δ {t}_{end}}{3600 * {Capa}_{i}} {I}_{dc} .$$

Each integral can be calculated numerically. In a first variant, the result of each integral can be found in a previously determined map giving the open-circuit voltage OCVᵢ as a function of the state of charge SOCᵢ. In a second variant, the result of each integral can be found using the trapezoidal method, or any equivalent method known to the person skilled in the art.

In the presence of the options described above, the first information ib1 can be determined by means of the following equation when it is equal to the total energy available for discharge E_{tot ref}:

$$ib 1 = {\sum }_{i = 1}^{i = N} [ {capa}_{BOL} * {SOHC}_{i} {\int }_{SOCmax , i}^{SOCend , i} {OCV}_{i} ( SOC ) dSOC - {I}_{dc}^{2} {\sum }_{k = 0}^{\frac{Δ {t}_{end}}{Te}} Te . {SOHR}_{i} * ( {R}_{0 , TrefBOL , i} + {R}_{1 , TreBOL , i} ) ( k ) ] .$$

where capa_{BOL}*SOHCᵢ=capaᵢ, SOHRᵢ*(R_{0, Tref BOL,i}+R_{1, Tref BOL,i})=(R_{0,i}+R_{1,i}), Te is the sampling period equivalent to the call frequency of the first information calculation function ib1 in the information estimation device DEI, and for example equal to 100 ms or 1 s, R_{0, Tref BOL,i} is the open-circuit resistance of the circuit representing the cell CE (i) at the reference temperature Tref and at the beginning of the cell CE's (i) life, and R_{1, Tref BOL,i} is the internal resistance of the cell CE (i) at the reference temperature Tref and at the beginning of the cell CE's (i) life.

This last equation of ib1 follows from the fact that the total available energy Eₜₒₜ (for the current operating temperature of the cellular battery BC) is given by the general equation:

$${E}_{tot} = {\sum }_{i = 1}^{I = N} {I}_{dc} {\int }_{tini}^{tend} {U}_{i} dt = {\sum }_{i = 1}^{i = N} [ {I}_{dc} {\int }_{tini}^{tend} {OCV ( t )}_{i} dt - {I}_{dc} {\int }_{tini}^{tend} {I}_{dc} ( {R}_{0 , i} ( t ) + {R}_{1 , i} ( t ) ) dt ] ,$$

which can be rewritten as follows:

$${E}_{tot} = {\sum }_{i = 1}^{i = N} [ {capa}_{i} {\int }_{SOCini , i}^{SOCend , i} {OCV}_{i} ( SOC ) dSOC - {I}_{dc}^{2} {\int }_{0}^{Δ {t}_{end}} ( {R}_{0 , i} + {R}_{1 , i} ) dt ] , where dt = \frac{Capa}{{I}_{dc}} \times dSOC ,$$

which in turn can be rewritten as:

$${E}_{tot} = {\sum }_{i = 1}^{i = N} [ {capa}_{i} {\int }_{SOCini , i}^{SOCend , i} {OCV}_{i} ( SOC ) dSOC - {I}_{dc}^{2} Te {{\int }^{\frac{Δ {t}_{end}}{Te}}}_{k = 0} ( {R}_{0 , i} + {R}_{1 , i} ) ( k ) ] ,$$

then as follows:

$${E}_{tot} = {\sum }_{i = 1}^{i = N} [ {capa}_{BOL} * {SOHC}_{i} {\int }_{SOCmax , i}^{SOCend , i} {OCV}_{i} ( SOC ) dSOC - {I}_{dc}^{2} Te . {\sum }_{k = 0}^{\frac{Δ {t}_{end}}{Te}} {SOHR}_{i} ( {R}_{0 , BOL , i} + {R}_{1 , BOL , i} ) ( k ) ] .$$

It shall be understood that the transition from Eₜₒₜ to E_{tot ref} is performed by replacing SOC_{ini,i} by SOC_{max,i} in the integral, as we are referring to the maximum energy at the beginning of the cell CE's life (i), and (R_{0.BOL,i}+R_{1,BOL,i}) by (R_{0,TrefBOL,i}+R_{1,TrefBOL,i}), because the temperature is the reference temperature Tref.

It should also be noted, as shown non-limitingly in FIG. 3, that step 10-40 can comprise a sub-step 40 in which a second item of information ib2 (n=2) is estimated, which is representative of the state of health of energy SOHE of the cellular battery BC, as a function of the first information ib1 and a useful energy at the beginning of life E_{tot BOL} of the cellular battery BC.

For example, the second information ib2 can be determined using the following equation when it is equal to the state of health of energy SOHE:

$$i b 2 = SOHE = 100 \frac{{E}_{tot Ref}}{{E}_{tot BOL}} .$$

Also, for example, when we want to take a production dispersion margin of N cells CE, the useful energy at the beginning of life E_{tot BOL} can be chosen equal to (E_{tot BOL_avg}−3σ), where E_{tot BOL_avg} is the average useful energy at the beginning of life and σ is the standard deviation.

It should also be noted, as shown in FIG. 2, that the CB battery computer (or the dedicated computer of the information estimation device DEI) may also include a mass memory MM1, in particular for temporarily storing the measurements of the voltage, current and internal temperature of the N cells CE and any intermediate data used in all its calculations and processing. Furthermore, this battery computer CB (or the dedicated computer of the information estimation device DEI) may also comprise an input interface IE for receiving at least the measurements of the voltage, current and internal temperature of the N cells CE for use in calculations or processing, possibly after formatting and/or demodulating and/or amplifying them, in a manner known per se, by means of a digital signal processor PR2. In addition, this battery computer CB (or the dedicated computer of the information estimation device DEI) may also include an output interface IS, in particular for delivering the first information ib1 and the possible second information ib2.

It will likewise be noted that also proposed is a computer program product (or IT program) comprising a set of instructions which, when executed by processing means of electronic circuit type (or hardware), such as, for example, the processor PR1, is suitable for implementing the method for estimating information described hereinbefore to estimate at least one item of information ibn in relation to the cellular battery BC of the system V.

1. A method for estimating information in relation to a cellular battery of a system comprising N cells suitable for storing electrical energy, where N>1, and each having a current state of charge, a current resistance state of health and a current capacity state of health, wherein it comprises a step wherein first information representative of a total energy available in said cellular battery is estimated as a function of said current resistance states of health, current capacity states of health and current states of charge, and of a time interval during which said cellular battery is allowed to discharge with a chosen discharge current and at a reference temperature.

2. The method according to claim 1, wherein in said step said first information is further estimated as a function of initial electrical energy storage capacities of each of said cells and initial maximum states of charge of each of said cells.

3. The method according to claim 1, wherein in said step said first information is further estimated as a function of selected theoretical models respectively representative of equivalent resistances of each of said cells.

4. The method according to claim 1, wherein in said step said first information is further estimated as a function of the sums of the open-circuit voltages of each of said cells for state-of-charge values between a maximum state-of-charge and a state-of-charge at the end of said time interval.

5. The method according to claim 1, wherein in said step said time interval is chosen as a function of a minimum cutoff voltage of a cell below which said discharging of the cellular battery with said chosen discharge current is prevented and/or of a minimum state of charge of a cell below which said discharging of the cellular battery with said chosen discharge current is prevented.

6. The method according to claim 5, wherein in said step a first theoretical time interval is determined as a function of said minimum cutoff voltage, of current electrical energy storage capacities of each of said cells, of said chosen discharge current, of chosen theoretical models representative respectively of equivalent resistances of each of said cells, and initial states of charge of each of said cells, and a second theoretical time interval as a function of said minimum state of charge, said selected discharge current, said current electrical energy storage capacities and said initial states of charge, then said time interval is selected by taking the shorter of said first and second theoretical time intervals.

7. The method according to claim 1, wherein, in said step, second information representative of an energy state of health of said cellular battery is estimated as a function of said first information and of a useful energy at the beginning-of-life of said cellular battery.

8. A computer program product comprising a set of instructions contained in a memory which, when executed by processing means, is suitable for implementing a method for estimating information according to claim 1 for estimating at least one item of information in relation to a cellular battery of a system comprising N cells able to store electrical energy, where N>1.

9. A device for estimating information for a system comprising a cellular battery comprising N cells suitable for storing electrical energy, where N>1, and each having a current state of charge, a current resistance state of health and a current capacity state of health, wherein it comprises at least one processor and at least one memory arranged to perform operations consisting of estimating first information representative of a total energy available in said cellular battery as a function of said current resistance states of health, current capacity states of health and current states of charge, and of a time interval during which said cellular battery is allowed to discharge with a chosen discharge current and at a reference temperature.

10. A system comprising a cellular battery having N cells suitable for storing electrical energy, where N>1, and each having a current state of charge, a current resistance state of health and a current capacity state of health, wherein it further comprises an information estimation device according to claim 9.
